(19) United States
(12) Patent Application Publication
(10) Pub. No.: US 2025/0191961 A1
(43) Pub. Date: Jun. 12, 2025

(54) SUBSTRATE GRIPPING APPARATUS

(71) Applicant: EBARA CORPORATION, Tokyo (JP)

(72) Inventor: SATOSHI AO, Tokyo (JP)

(73) Assignee: EBARA CORPORATION, Tokyo (JP)

(21) Appl. No.: 18/970,833

(22) Filed: Dec. 5, 2024

(30) Foreign Application Priority Data
Dec. 12, 2023 (JP) 2023-209034

(51) Int. Cl. H01L 21/687

(52) U.S. Cl. CPC H01L 21/68721; H01L 21/68785

(57) ABSTRACT

A substrate gripping apparatus includes: a support member having a follower pin and a substrate support surface; a movable rod movable relatively with respect to the support member; and a chuck for gripping an edge of a substrate. The chuck has an elongated guide hole in a bent shape, and the follower pin is disposed within the elongated guide hole and is movable relatively with respect to the elongated guide hole. The elongated guide hole includes a first section, a second section, and a connecting section, the first section extends upward from the connecting section, and the second section extends in a direction different from the first section.

### CROSS-REFERENCE TO RELATED APPLICATION

This application claims the priority benefit of Japan application serial no. 2023-209034, filed on Dec. 12, 2023. The entirety of the above-mentioned patent application is hereby incorporated by reference herein and made a part of this specification.

### BACKGROUND

### Technical Field

The disclosure relates to a substrate gripping apparatus, and particularly, to a substrate gripping apparatus applicable to a cleaning apparatus and a drying apparatus for a substrate such as a wafer.

### Related Art

In a semiconductor device fabrication process, a cleaning process or a drying process of a substrate is performed after a polishing process or a plating process. For example, in a cleaning process of a substrate, the substrate is rotated while being gripped by a substrate gripping apparatus, and in this state, a cleaning solution is supplied to the substrate. A scrub cleaning tool composed of a sponge and the like performs scrub cleaning on a surface of the substrate while moving on the surface of the substrate which rotates.

FIG. 10 is a view showing an example of a conventional substrate gripping apparatus. This substrate gripping apparatus includes a chuck 501 connected to a movable rod 500. The chuck 501 is rotatable around a pivot shaft 503. The movable rod 500 has an elongated hole 505 extending horizontally, and the chuck 501 has a pin 507 disposed within the elongated hole 505. With the movable rod 500 moving upward and downward, the chuck 501 rotates around the pivot shaft 503. FIG. 10 shows a state in which the movable rod 500 lowers and the chuck 501 grips an edge of the substrate W.

The chuck 501 moves to cover the edge of the substrate W and grip the substrate W. A distance from an outermost end of the substrate W to a tip of the chuck 501 will be referred to as an overlap amount L in this specification. The overlap amount L affects not only stability of gripping the substrate W but also a cleaning result of the substrate W. In other words, if the overlap amount L is too small, the substrate W becomes more likely to detach from the chuck 501. In contrast, if the overlap amount L is too large, a cleaning region of the substrate W decreases. That is, since the scrub cleaning tool cleans the surface of the substrate W within a range without contacting the chuck 501 which rotates, as the overlap amount L increases, the cleaning region of the substrate W decreases.

FIG. 11 is a view showing a state in which the chuck 501 grips a substrate W that is thicker than the substrate W shown in FIG. 10. As can be learned from a comparison between FIG. 10 and FIG. 11, the overlap amount L varies depending on a thickness of the substrate W. In other words, the stability of gripping the substrate W and the cleaning result of the substrate W may vary depending on the thickness of the substrate W. The same may also occur in the case where the substrate gripping apparatus is applied to a drying apparatus.

FIG. 12 is a view of a time when the chuck 501 is to grip a warped substrate W, and FIG. 13 is a view of a time when the chuck 501 is to grip a substrate W that is even thicker than the substrate W shown in FIG. 11. As shown in FIG. 12 and FIG. 13, when the edge of a warped substrate W or a thick substrate W is outside a movable range of the chuck 501, the chuck 501 cannot grip the substrate W.

### RELATED ART DOCUMENTS

### Patent Documents

[Patent Document 1] Japanese Patent Application Laid-Open No. 2014-133642

### SUMMARY

In an embodiment, a substrate gripping apparatus for gripping a substrate is provided. The substrate gripping apparatus includes: a support member having a follower pin and a substrate support surface; a movable rod movable relatively with respect to the support member; a chuck for gripping an edge of the substrate; and a connecting shaft rotatably connecting the chuck to the movable rod. The chuck has an elongated guide hole in a bent shape. The follower pin is disposed within the elongated guide hole and is movable relatively with respect to the elongated guide hole. The elongated guide hole includes a first section, a second section, and a connecting section located within the first section and the second section. The first section extends upward from the connecting section. The second section extends in a direction different from the first section.

In an embodiment, with the follower pin located within the first section, the first section is parallel to a moving direction of the movable rod.

In an embodiment, the elongated guide hole is adjacent to the connecting shaft.

In an embodiment, the second section is located between the first section and the connecting shaft.

In an embodiment, a substrate gripping apparatus for gripping a substrate is provided. The substrate gripping apparatus includes: a support member having a follower pin and a substrate support surface; a movable rod movable relatively with respect to the support member; a chuck for gripping an edge of the substrate; and a connecting shaft rotatably connecting the chuck to the movable rod. The chuck has an elongated guide hole in a bent shape. The follower pin is disposed within the elongated guide hole and is movable relatively with respect to the elongated guide hole. The elongated guide hole includes a first section, a second section, and a connecting section located within the first section and the second section. The second section extends in a direction different from the first section. With the follower pin located within the first section, the first section is parallel to a moving direction of the movable rod.

In an embodiment, a substrate gripping apparatus for gripping a substrate is provided. The substrate gripping apparatus includes: a support member having a substrate support surface; a movable rod movable relatively with respect to the support member; a chuck for gripping an edge of the substrate; and a connecting shaft rotatably connecting the chuck to the movable rod. The support member has an elongated guide hole in a bent shape. The chuck has a follower pin. The follower pin is disposed within the elongated guide hole and is movable relatively with respect to the elongated guide hole. The elongated guide hole includes a first section, a second section, and a connecting section located within the first section and the second section. The first section extends downward from the connecting section. The second section extends in a direction different from the first section.

In an embodiment, the first section is parallel to a moving direction of the movable rod.

In an embodiment, the elongated guide hole is adjacent to the connecting shaft.

In an embodiment, the first section is located between the second section and the connecting shaft.

In an embodiment, a substrate gripping apparatus for gripping a substrate is provided. The substrate gripping apparatus includes: a support member having a substrate support surface; a movable rod movable relatively with respect to the support member; a chuck for gripping an edge of the substrate; and a connecting shaft rotatably connecting the chuck to the movable rod. The support member has an elongated guide hole in a bent shape. The chuck has a follower pin. The follower pin is disposed within the elongated guide hole and is movable relatively with respect to the elongated guide hole. The elongated guide hole includes a first section, a second section, and a connecting section located within the first section and the second section. The second section extends in a direction different from the first section. The first section is parallel to a moving direction of the movable rod.

When the follower pin moves relatively with respect to the elongated guide hole within the first section, the chuck moves in a direction perpendicular to a surface of the substrate. Thus, even when the substrate is thicker than expected or the substrate is warped, the chuck can approach the edge of the substrate from above and grip the edge of the substrate.

### BRIEF DESCRIPTION OF THE DRAWINGS

FIG. 1 is a vertical cross-sectional view showing an embodiment of a substrate gripping apparatus.

FIG. 2 is a plan view of the substrate gripping apparatus shown in FIG. 1.

FIG. 3 is a view showing a state in which movable rods are moved upward by a lift mechanism.

FIG. 4 is an enlarged cross-sectional view of a chuck, the movable rod, and a support member.

FIG. 5 is a view showing a state in which the chuck separates from a substrate on a substrate support surface.

FIG. 6 is a view showing the chuck when gripping substrates of different thicknesses.

FIG. 7 is a vertical cross-sectional view showing another embodiment of the substrate gripping apparatus.

FIG. 8 is a view showing a state in which the chuck separates from the substrate on the substrate support surface.

FIG. 9 is a view showing the chuck when gripping substrates of different thicknesses.

FIG. 10 is a view showing an example of a conventional substrate gripping apparatus.

FIG. 11 is a view showing a state in which a chuck grips a substrate thicker than a substrate shown in FIG. 10.

FIG. 12 is a view of a time when the chuck is to grip a warped substrate.

FIG. 13 is a view showing a state in which the chuck grips a substrate thicker than the substrate shown in FIG. 11.

### DESCRIPTION OF THE EMBODIMENTS

Embodiments of the disclosure provide a substrate gripping apparatus capable of reliably gripping a substrate regardless of a thickness or a warped shape of a substrate.

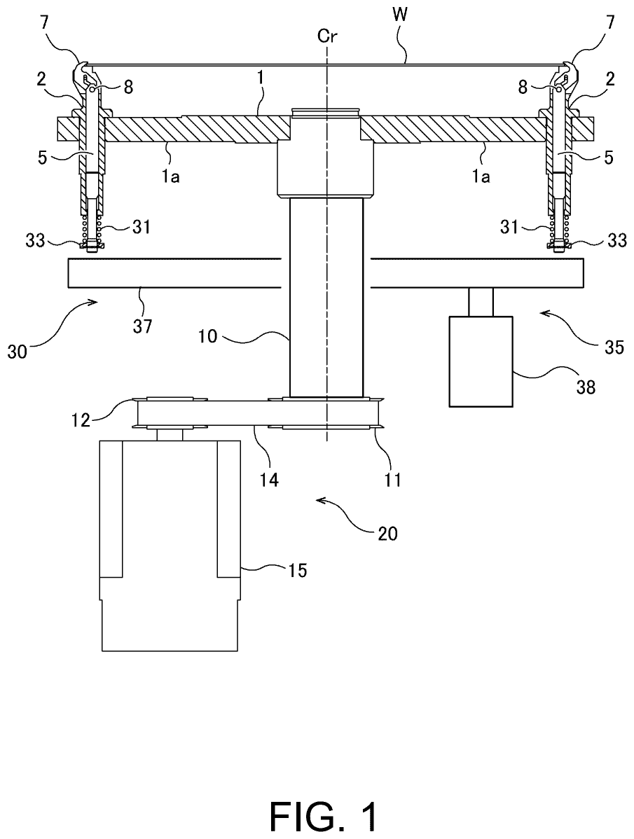

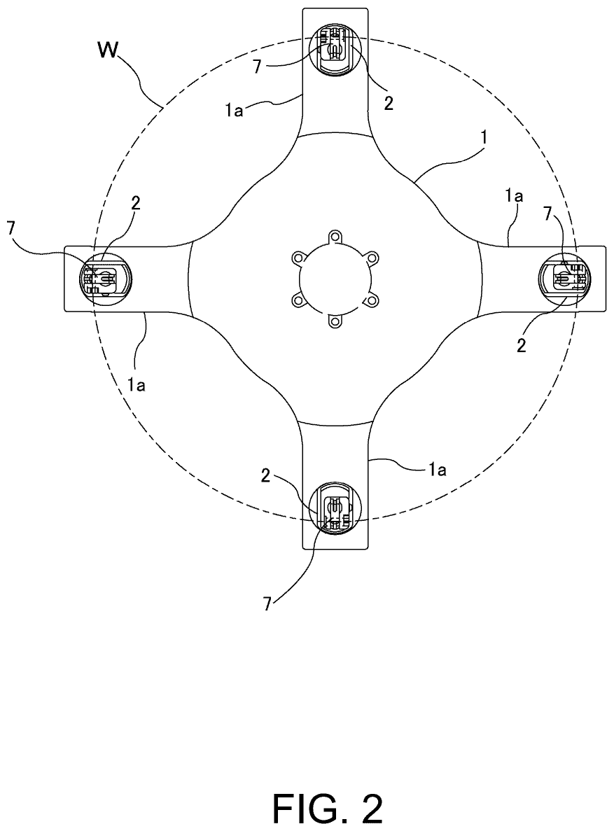

Hereinafter, embodiments of the disclosure will be described with reference to the drawings. FIG. 1 is a vertical cross-sectional view showing an embodiment of a substrate gripping apparatus. FIG. 2 is a plan view of the substrate gripping apparatus shown in FIG. 1. As shown in FIG. 1 and FIG. 2, the substrate gripping apparatus for gripping a substrate W includes a base 1 having four arms 1a, four support members 2 respectively supported at tips of the four arms 1a, and four movable rods 5 movably supported by the four support members 2. Each movable rod 5 is movable relatively with respect to the corresponding support member 2. More specifically, the four movable rods 5 are movable upward and downward with respect to the four support members 2 and the base 1. An example of the substrate W is a circular wafer.

The substrate gripping apparatus further includes four chucks 7 for gripping an edge of the substrate W, and four connecting shafts 8 that rotatably connect the four chucks 7 respectively to the four movable rods 5. In this embodiment, four arms 1a, four support members 2, four chucks 7, four movable rods 5, and four connecting shafts 8 are provided, but the numbers of the arms 1a, the support members 2, the chucks 7, the movable rods 5, and the connecting shafts 8 are not limited to this embodiment, and five or more arms 1a, five or more support members 2, five or more chucks 7, five or more movable rods 5, and five or more connecting shafts 8 may also be provided.

The substrate gripping apparatus further includes a rotating shaft 10 to which the base 1 is fixed, and a rotating mechanism 20 that rotates the rotating shaft 10 around a rotation center Cr. The base 1 is fixed to an upper end of the rotating shaft 10, and the rotating shaft 10 is rotatably supported by a bearing (not shown). The rotating mechanism 20 of this embodiment has pulleys 11 and 12, a belt 14, and a motor 15. The rotating shaft 10 is connected to the motor 15 via the pulleys 11 and 12 and the belt 14, and by driving the motor 15, the base 1 rotates around the rotation center Cr. The substrate W is gripped by the chucks 7 and is rotated around the rotation center Cr by the motor 15. The specific configuration of the rotating mechanism 20 is not limited to this embodiment, and may have other configurations as long as it is capable of rotating the substrate W gripped by the chucks 7.

The substrate gripping apparatus includes an up-down moving device 30 that simultaneously moves the four movable rods 5 upward and downward. In an embodiment, the up- down moving device 30 includes four springs 31 that respectively push the four movable rods 5 downward. The movable rod 5 has a spring stopper 33, and the spring 31 is disposed between a lower end of the support member 2 and the spring stopper 33. A force of the spring 31 pushes the spring stopper 33 downward, and thereby the movable rod 5 is biased downward by the spring 31.

The up-down moving device 30 further includes a lift mechanism 35 that simultaneously raises the four movable rods 5. The lift mechanism 35 is configured to move the movable rods 5 upward against the force of the springs 31. The lift mechanism 35 includes a lifter 37 located below the four movable rods 5, and a lift actuator 38 that moves the lifter 37 upward and downward. Specific examples of the lift actuator 38 include an air cylinder and an electric linear actuator. When the substrate W is gripped by the chucks 7, the lifter 37 is not in contact with the movable rods 5.

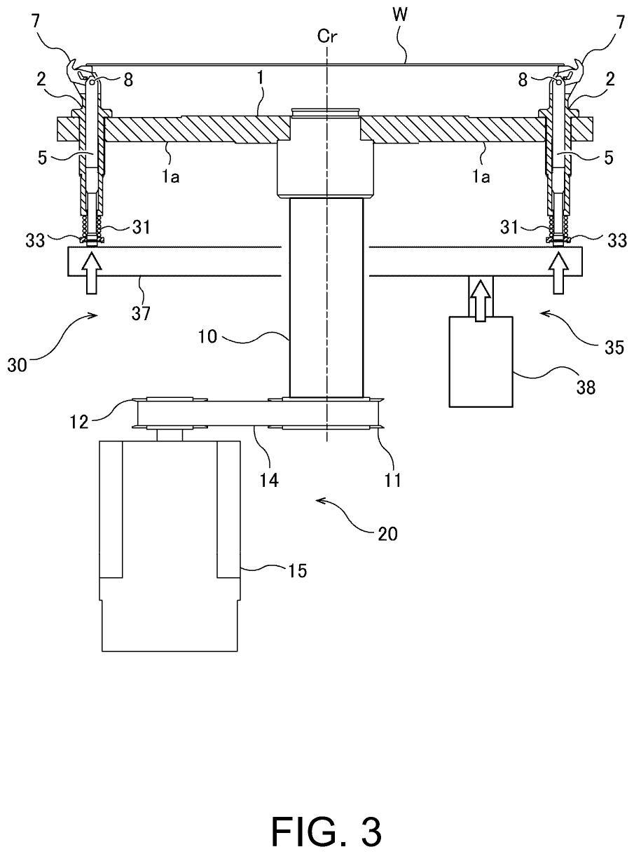

FIG. 3 is a view showing a state in which the movable rods 5 are moved upward by the lift mechanism 35. As shown in FIG. 3, with the lift actuator 38 raising the lifter 37, the lifter 37 comes into contact with lower ends of the four movable rods 5, and further moves the four movable rods 5 upward simultaneously. With the movable rods 5 moving upward, the chucks 7 open, and the substrate W is released from the chucks 7.

With the lift actuator 38 lowering the lifter 37, as shown in FIG. 1, the lifter 37 separates from the movable rods 5, and the movable rods 5 are moved downward by the springs 31. With the movable rods 5 moving downward, the chucks 7 close, and the substrate W is gripped by the chucks 7.

In this embodiment, the up-down moving device 30 moving the four movable rods 5 upward and downward includes the springs 31 and the lift mechanism 35, but the up-down moving device 30 is not limited to the combination of the springs 31 and the lift mechanism 35 as long as it is capable of simultaneously moving the four movable rods 5 upward and downward. For example, the up-down moving device 30 may also be an actuator (e.g., an air cylinder or an electric linear actuator) connected to the four movable rods 5.

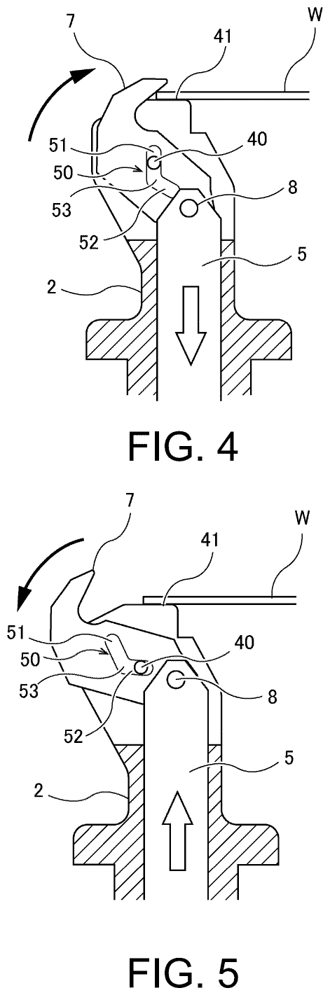

FIG. 4 is an enlarged cross-sectional view of the chuck 7, the movable rod 5, and the support member 2. The support member 2 has a follower pin 40 and a substrate support surface 41. The substrate W is transported to the substrate gripping apparatus by a transport robot (not shown), and the edge of the substrate W is placed on the substrate support surface 41. The edge of the substrate W is supported by the substrate support surface 41. The chuck 7 is rotatably connected to the movable rod 5 by the connecting shaft 8. The movable rod 5 is capable of moving upward and downward relatively with respect to the support member 2, which includes the follower pin 40 and the substrate support surface 41.

The chuck 7 has an elongated guide hole 50 in a bent shape, and the follower pin 40 is disposed within the elongated guide hole 50. A width of the elongated guide hole 50 is larger than a diameter of the follower pin 40, and the follower pin 40 is movable relatively with respect to the elongated guide hole 50. The elongated guide hole 50 may be a through-hole that penetrates from one lateral surface of the chuck 7 to another lateral surface on the opposite side, or may be a groove formed on one lateral surface of the chuck 7. In other words, examples of the elongated guide hole 50 include a through-hole in a bent elongated hole shape and a bent groove.

The elongated guide hole 50 has a first section 51, a second section 52, and a connecting section 53. The connecting section 53 is located between the first section 51 and the second section 52. The first section 51 extends upward from the connecting section 53, and the second section 52 extends in a direction different from the first section 51. The first section 51 extends in a straight line shape, and the second section 52 also extends in a straight line shape. The second section 52 may also be curved. In this embodiment, the second section 52 extends to a radially inner side from the connecting section 53. In this specification, the “radially inner side” refers to a radially inner side of a circle (an imaginary circle) centered on the rotation center Cr of the substrate gripping apparatus shown in FIG. 1 and FIG. 2. As shown in FIG. 4, in this embodiment, the second section 52 extends from the connecting section 53 toward the connecting shaft 8.

The elongated guide hole 50 is adjacent to the connecting shaft 8. More specifically, the second section 52 is adjacent to the connecting shaft 8. The second section 52 is located between the first section 51 and the connecting shaft 8. In other words, a distance between the second section 52 and the connecting shaft 8 is shorter than a distance between the first section 51 and the connecting shaft 8. The first section 51 is longer than the second section 52, and a length of the first section 51 is greater than a thickness of the substrate W. In an embodiment, the length of the first section 51 is 1.1 to 1.5 times a sum of the thickness of the substrate W to be gripped and an expected warpage of the substrate W. An angle between the first section 51 and the second section 52 is 90 degrees or more and less than 180 degrees.

As shown in FIG. 4, with the movable rod 5 lowering, the chuck 7 rotates around the follower pin 40 in a direction approaching the substrate support surface 41, and the substrate W on the substrate support surface 41 is gripped by the chuck 7. As shown in FIG. 5, with the movable rod 5 rising, the chuck 7 rotates around the follower pin 40 in a direction away from the substrate support surface 41, and the chuck 7 separates from the substrate W on the substrate support surface 41. As shown in FIG. 4 and FIG. 5, as the chuck 7 rotates, the follower pin 40 moves within the elongated guide hole 50. In actual movement, since the position of the follower pin 40 is fixed, as the chuck 7 rotates, the elongated guide hole 50 moves relatively with respect to the follower pin 40.

When the chuck 7 grips the substrate W, as shown in FIG. 4, the follower pin 40 is located within the first section 51. After the chuck 7 separates from the substrate W, as shown in FIG. 5, the follower pin 40 is located within the second section 52. When the follower pin 40 is located within the first section 51, the first section 51 is parallel to a moving direction of the movable rod 5, as shown in FIG. 4. Herein, “parallel” includes not only the case where the first section 51 is completely parallel to the moving direction of the movable rod 5, but also includes, as described later, the case where the first section 51 is slightly inclined from the moving direction of the movable rod 5, as long as the chuck 7 can grip substrates of different thicknesses.

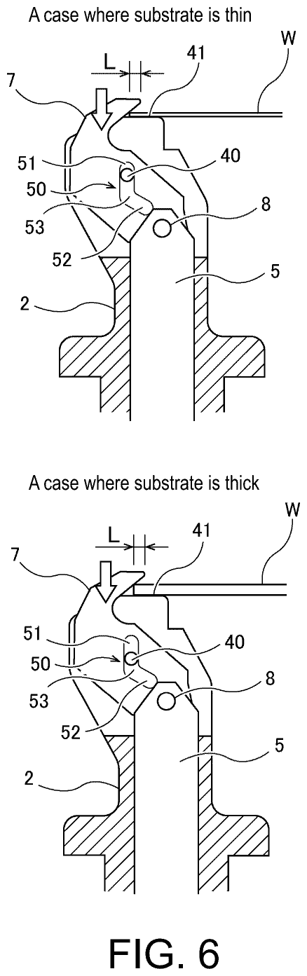

FIG. 6 is a view showing the chuck 7 when gripping substrates of different thicknesses.

When the chuck 7 grips the substrate W, the chuck 7 is guided by engagement between the follower pin 40 and the first section 51 of the elongated guide hole 50 and lowers in a direction perpendicular to a surface of the substrate W. In other words, when the follower pin 40 is located within the first section 51, the first section 51 is perpendicular to the surface of the substrate W. Thus, even in a case where the substrate W is thicker than expected, or in a case where the substrate W is warped, the chuck 7 can approach the edge of the substrate W from above and grip the edge of the substrate W.

In particular, as shown in FIG. 6, since the chuck 7 lowers in a direction perpendicular to the surface of the substrate W when coming into contact with the substrate W, an overlap amount L in the case where the substrate W is thin is the same as an overlap amount L in the case where the substrate W is thick. The overlap amount L is a distance from an outermost end of the substrate W to a tip of the chuck 7. Since the overlap amount L is the same regardless of the thickness of the substrate W, the chuck 7 can stably grip substrates W of various thicknesses. Furthermore, in the case where the substrate gripping apparatus is applied to a substrate processing apparatus such as a substrate cleaning apparatus or a substrate drying apparatus, a substrate processing range can be kept constant.

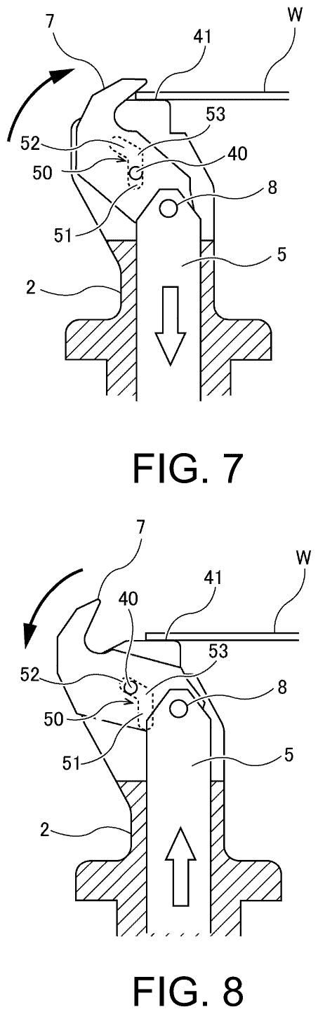

FIG. 7 is a view showing another embodiment of the substrate gripping apparatus. Configurations and actions of this embodiment that are not particularly described are the same as those of the embodiment described with reference to FIG. 1 to FIG. 6, so repeated descriptions thereof will be omitted. In the embodiment shown in FIG. 7, the support member 2 has an elongated guide hole 50 in a bent shape, and the chuck 7 includes a follower pin 40. The follower pin 40 is disposed within the elongated guide hole 50 and is movable relatively with respect to the elongated guide hole 50. The elongated guide hole 50 may be a through-hole that penetrates from one lateral surface of the support member 2 to another lateral surface on the opposite side, or may be a groove formed on one lateral surface of the support member 2. In other words, examples of the elongated guide hole 50 include a through-hole in a bent elongated hole shape and a bent groove.

The elongated guide hole 50 includes a first section 51, a second section 52, and a connecting section 53. The connecting section 53 is located between the first section 51 and the second section 52. The first section 51 extends downward from the connecting section 53, and the second section 52 extends in a direction different from the first section 51. The first section 51 extends in a straight line shape, and the second section 52 also extends in a straight line shape. The second section 52 may also be curved. In this embodiment, the second section 52 extends to a radially outer side from the connecting section 53. In this specification, the “radially outer side” refers to a radially outer side of a circle (an imaginary circle) centered on the rotation center Cr of the substrate gripping apparatus shown in FIG. 1 and FIG. 2. The second section 52 of this embodiment extends diagonally upward to the radially outer side from the connecting section 53.

The elongated guide hole 50 is adjacent to the connecting shaft 8. More specifically, the first section 51 is adjacent to the connecting shaft 8. The first section 51 is located between the second section 52 and the connecting shaft 8. In other words, a distance between the first section 51 and the connecting shaft 8 is shorter than a distance between the second section 52 and the connecting shaft 8. The first section 51 is longer than the second section 52, and a length of the first section 51 is greater than a thickness of the substrate W. In an embodiment, the length of the first section 51 is 1.1 to 1.5 times a sum of the thickness of the substrate W to be gripped and an expected warpage of the substrate W. An angle between the first section 51 and the second section 52 is 90 degrees or more and less than 180 degrees.

As shown in FIG. 7, with the movable rod 5 lowering, the chuck 7 rotates around the follower pin 40 in a direction approaching the substrate support surface 41, and the substrate on the substrate support surface 41 is gripped by the chuck 7. As shown in FIG. 8, with the movable rod 5 rising, the chuck 7 rotates around the follower pin 40 in a direction away from the substrate support surface 41, and the chuck 7 separates from the substrate on the substrate support surface 41. As shown in FIG. 7 and FIG. 8, as the chuck 7 rotates, the follower pin 40 moves relatively with respect to the elongated guide hole 50.

When the chuck 7 grips the substrate W, as shown in FIG. 7, the follower pin 40 is located within the first section 51. After the chuck 7 separates from the substrate W, as shown in FIG. 8, the follower pin 40 is located within the second section 52. As shown in FIG. 7, the first section 51 is parallel to a moving direction of the movable rod 5. Herein, “parallel” includes not only the case where the first section 51 is completely parallel to the moving direction of the movable rod 5, but also includes the case where the first section 51 is slightly inclined from the moving direction of the movable rod 5, as long as the chuck 7 can grip substrates of different thicknesses.

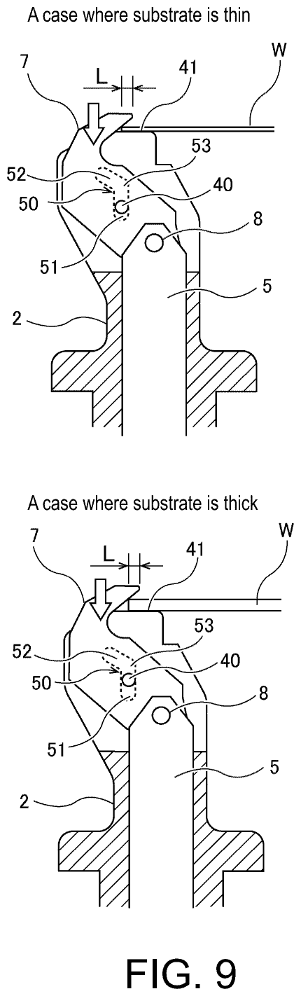

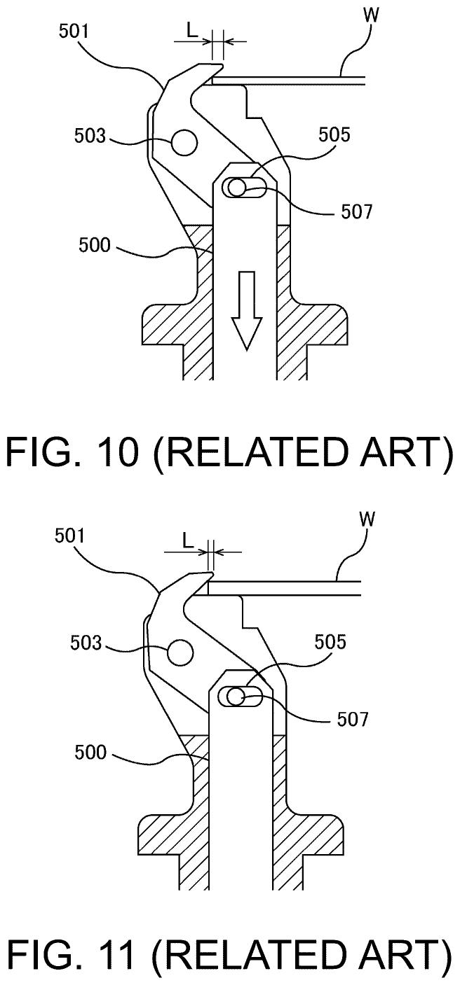

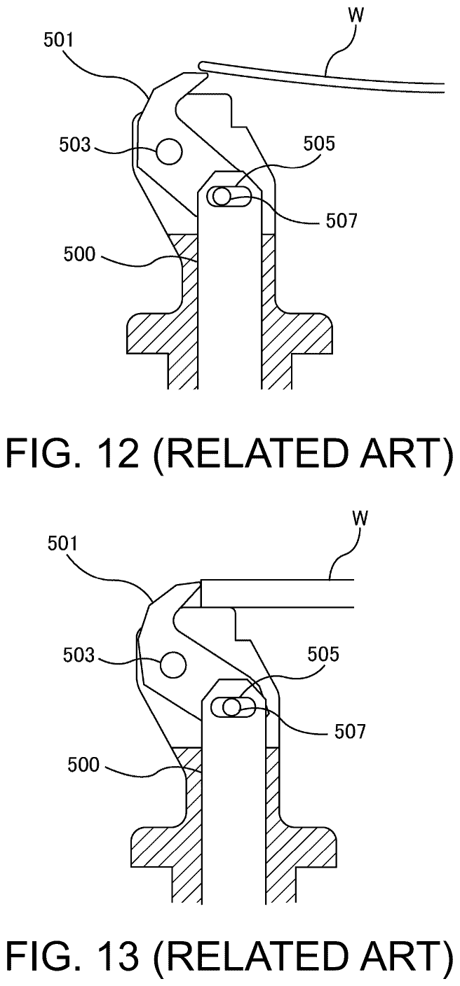

FIG. 9 is a view showing the chuck 7 when gripping substrates of different thicknesses. When the chuck 7 grips the substrate W, the chuck 7 is guided by engagement between the follower pin 40 and the first section 51 of the elongated guide hole 50 and lowers in a direction perpendicular to the surface of the substrate W. In other words, the first section 51 is perpendicular to the surface of the substrate W. Thus, even in a case where the substrate W is thicker than expected, or in a case where the substrate W is warped, the chuck 7 can approach the edge of the substrate W from above and grip the edge of the substrate W.

In particular, as shown in FIG. 9, since the chuck 7 lowers in a direction perpendicular to the surface of the substrate W when coming into contact with the substrate W, an overlap amount L in the case where the substrate W is thin is the same as an overlap amount L in the case where the substrate W is thick. Thus, the chuck 7 can stably grip the substrate W. Furthermore, in the case where the substrate gripping apparatus is applied to a substrate processing apparatus such as a substrate cleaning apparatus or a substrate drying apparatus, a substrate processing range can be kept constant.

The shape of the elongated guide hole 50 is not limited to the embodiments described with reference to FIG. 1 to FIG. 9. For example, the connecting section 53 may have a curved shape that smoothly connects the first section 51 and the second section 52.

The substrate gripping apparatus of the embodiments described with reference to FIG. 1 to FIG. 9 is configured to grip the substrate W horizontally, but the configuration of the substrate gripping apparatus is not limited to these embodiments. For example, the substrate gripping apparatus may also be configured to grip the substrate W in a vertical posture or an inclined posture.

The above embodiments have been described to enable a person having ordinary skill in the art to which the disclosure belongs to implement the disclosure. Obviously, various modification examples of the above embodiments may be made by those skilled in the art, and the technical concept of the disclosure may be applied to other embodiments. Thus, the disclosure is not limited to the described embodiments, but is to be interpreted in the broadest scope in accordance with the technical concept defined by the claims.

What is claimed is:

1. A substrate gripping apparatus for gripping a substrate, the substrate gripping apparatus comprising:
a support member having a follower pin and a substrate support surface;
a movable rod movable relatively with respect to the support member;
a chuck for gripping an edge of the substrate; and
a connecting shaft rotatably connecting the chuck to the movable rod, wherein
the chuck has an elongated guide hole in a bent shape,
the follower pin is disposed within the elongated guide hole and is movable relatively with respect to the elongated guide hole,
the elongated guide hole comprises a first section, a second section, and a connecting section located within the first section and the second section,
the first section extends upward from the connecting section, and
the second section extends in a direction different from the first section.

2. The substrate gripping apparatus according to claim 1, wherein with the follower pin located within the first section, the first section is parallel to a moving direction of the movable rod.

3. The substrate gripping apparatus according to claim 1, wherein the elongated guide hole is adjacent to the connecting shaft.

4. The substrate gripping apparatus according to claim 1, wherein the second section is located between the first section and the connecting shaft.

5. A substrate gripping apparatus for gripping a substrate, the substrate gripping apparatus comprising:
a support member having a follower pin and a substrate support surface;
a movable rod movable relatively with respect to the support member;
a chuck for gripping an edge of the substrate; and
a connecting shaft rotatably connecting the chuck to the movable rod, wherein
the chuck has an elongated guide hole in a bent shape,
the follower pin is disposed within the elongated guide hole and is movable relatively with respect to the elongated guide hole,
the elongated guide hole comprises a first section, a second section, and a connecting section located within the first section and the second section,
the second section extends in a direction different from the first section, and
with the follower pin located within the first section, the first section is parallel to a moving direction of the movable rod.

6. A substrate gripping apparatus for gripping a substrate, the substrate gripping apparatus comprising:
a support member having a substrate support surface;
a movable rod movable relatively with respect to the support member;
a chuck for gripping an edge of the substrate; and
a connecting shaft rotatably connecting the chuck to the movable rod, wherein
the support member has an elongated guide hole in a bent shape,
the chuck has a follower pin,
the follower pin is disposed within the elongated guide hole and is movable relatively with respect to the elongated guide hole,
the elongated guide hole comprises a first section, a second section, and a connecting section located within the first section and the second section,
the first section extends downward from the connecting section, and
the second section extends in a direction different from the first section.

7. The substrate gripping apparatus according to claim 6, wherein the first section is parallel to a moving direction of the movable rod.

8. The substrate gripping apparatus according to claim 6, wherein the elongated guide hole is adjacent to the connecting shaft.

9. The substrate gripping apparatus according to claim 6, wherein the first section is located between the second section and the connecting shaft.

10. A substrate gripping apparatus for gripping a substrate, the substrate gripping apparatus comprising:
a support member having a substrate support surface;
a movable rod movable relatively with respect to the support member;
a chuck for gripping an edge of the substrate; and
a connecting shaft rotatably connecting the chuck to the movable rod, wherein
the support member has an elongated guide hole in a bent shape,
the chuck has a follower pin,
the follower pin is disposed within the elongated guide hole and is movable relatively with respect to the elongated guide hole,
the elongated guide hole comprises a first section, a second section, and a connecting section located within the first section and the second section,
the second section extends in a direction different from the first section, and
the first section is parallel to a moving direction of the movable rod.
